(19) United States
(12) Patent Application Publication
(10) Pub. No.: US 2026/0052753 A1
(43) Pub. Date: Feb. 19, 2026

(54) METHODS OF MANUFACTURING SEMICONDUCTOR DEVICES

(71) Applicant: Samsung Electronics Co., Ltd., Suwon-si (KR)

(72) Inventors: Jeongeun Song, Suwon-si (KR); Junggil Yang, Suwon-si (KR); Soyun Jeong, Suwon-si (KR)

(21) Appl. No.: 19/048,226

(22) Filed: Feb. 7, 2025

(30) Foreign Application Priority Data
Aug. 14, 2024 (KR) 10-2024-0108936

(51) Int. Cl. H10D 84/01

(52) U.S. Cl. CPC H10D 84/0128; H10D 84/0149; H10D 84/0151

(57) ABSTRACT

A method of manufacturing a semiconductor device includes forming a substrate laminate, which is configured as: a first base layer, a first etch-stop layer including silicon germanium, a second base layer, a second etch-stop layer including silicon germanium, and a third base layer. An opening is formed in the substrate laminate by etching a partial region therein. Monocrystalline silicon is grown within the opening. A plurality of channel layers are formed on the substrate laminate, and configured to be spaced apart in a first direction parallel to a first surface of the substrate laminate, a plurality of gate structures are formed extending in a second direction crossing the first direction, and source/drains are formed and located on both sides of each of the channel layers. The first base layer, the first etch-stop layer, the second base layer, and the second etch-stop layer are also removed.

### REFERENCE TO PRIORITY APPLICATION

This application claims priority under 35 U.S. C. § 119 to Korean Patent Application No. 10-2024-0108936, Aug. 14, 2024, the disclosure of which is hereby incorporated herein by reference.

### BACKGROUND

The present disclosure relates to methods of manufacturing semiconductor devices.

A semiconductor is a material belonging to an intermediate region between low resistance conductor and high resistance electrical insulator, and refers to a material that can conduct electricity when predetermined conditions are met. Various semiconductor devices can be manufactured by using such a semiconductor material; for example, highly integrated memory devices and the like can be manufactured using semiconductor manufacturing methods.

As the electronics industry continues to advance, there is a growing demand for specific characteristics of the semiconductor devices. For example, there is an increasing demand for higher reliability, higher speed, and/or higher multifunctionality of the semiconductor devices. In order to meet these demand characteristics, structures in a semiconductor device are becoming increasingly complex and integrated.

### SUMMARY

The present disclosure provide methods of manufacturing semiconductor devices having an improved reliability and performance.

An embodiment of a method of manufacturing a semiconductor device may include forming a substrate laminate, which includes a first base layer, a first etch-stop layer, a second base layer, a second etch-stop layer, and a third base layer, and forming an opening by etching a portion of the substrate laminate, and then growing monocrystalline silicon in the opening. A plurality of channel layers are provided, which are arranged on the substrate laminate and are spaced apart in a first direction parallel to a first surface of the substrate laminate. A plurality of gate structures are provided, which extend in a second direction crossing the first direction. Source/drains are provided, and are located on both sides of each of the channel layers. The first base layer, the first etch-stop layer, the second base layer, and the second etch-stop layer are removed. In some of these embodiments, the first and second etch-stop layers include silicon germanium.

A method of manufacturing a semiconductor device may include forming a substrate laminate including a first region, which contains a first base layer, a first etch-stop layer, a second base layer, second etch-stop layer and a third base layer, and a second region, which contains the first base layer, the first etch-stop layer, the second base layer and the third base layer. A plurality of channel layers are formed and arranged on the first region, and the second region is formed to be spaced apart in a first direction parallel to a first surface of the substrate laminate. A plurality of gate structures are provided, which extend in a second direction crossing the first direction. Source/drain patterns are provided, which are located on both sides of each of the channel layers in the first region and located in a recess region of the substrate laminate. Source/drain regions are also provided, which are located on the both sides of the each of the channel layers in the second region and are formed by doping the substrate laminate. The substrate laminate may also be etched, and the first, second and third base layers and the first and second etch-stop layers may include different materials.

A manufacturing method of a semiconductor device may include forming a substrate laminate including a first base layer, a first etch-stop layer, a second base layer, a second etch-stop layer, and a third base layer, forming an opening by etching a partial region of the third base layer, the second etch-stop layer, and the second base layer of the substrate laminate, growing monocrystalline silicon in the opening, removing the first base layer, removing the first etch-stop layer, removing the second base layer: removing the second etch-stop layer, and decreasing a thickness of the third base layer, where the first to the third base layer may include silicon, and where the first etch-stop layer and the second etch-stop layer may include silicon germanium.

According to embodiments, methods of manufacturing semiconductor devices to minimize process distributions may be provided.

### BRIEF DESCRIPTION OF THE DRAWINGS

FIG. 1 is a top plan view showing a semiconductor device according to an embodiment.

FIG. 2 is a cross-sectional view of a semiconductor device taken along line II-II′ of FIG. 1.

FIG. 3 is a cross-sectional view of a semiconductor device taken along line III-III′ of FIG. 1.

FIG. 4 is a cross-sectional view of a semiconductor device taken along line IV-IV′ of FIG. 1.

FIG. 5 shows the same cross-section as FIG. 2 according to another embodiment.

FIG. 6 to FIG. 23 illustrate methods of manufacturing semiconductor devices according to embodiments of the invention.

### DETAILED DESCRIPTION OF EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure. To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. Thus, in the drawings, the thicknesses of layers, films, panels, regions, areas, etc., may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements. Further, throughout the specification, the phrase “in a plan view” means when an object portion is viewed from above, and the phrase “in a cross-sectional view” means when a cross-section taken by vertically cutting an object portion is viewed from the side.

In the drawings for a semiconductor device according to an embodiment, as a mere example, gate-all-around (GAA) and multi-bridge-channel field effect transistor (MBCFET™) including nanowires or nanosheets are illustrated, but it is not limited thereto. Depending on the embodiment, the semiconductor device may include a fin-type transistor (FinFET) including a channel region of a fin pattern shape, a tunneling transistor (tunneling FET), a 3D stack field effect transistor (3D-SFET) structure, complementary field effect transistor (CFET) structure.

Furthermore, as used herein, the following reference numerals and corresponding regions/layers will be identified as: 10: substrate; A1: first region; A2: second region; 150: source/drain pattern; 160: source/drain region; 170: interlayer insulating layer; 180: penetration electrode; 190: separation insulation layer; 21: first base layer; 22: second base layer; 23: third base layer; 31: first etch-stop layer; 32: second etch-stop layer; STI: device isolation trench.

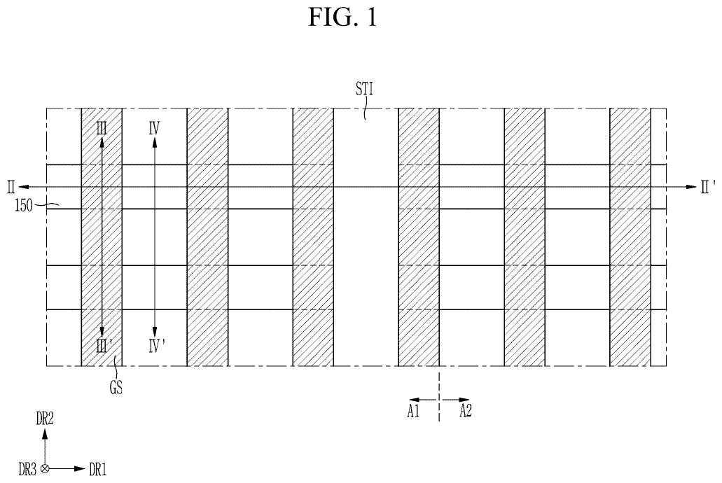

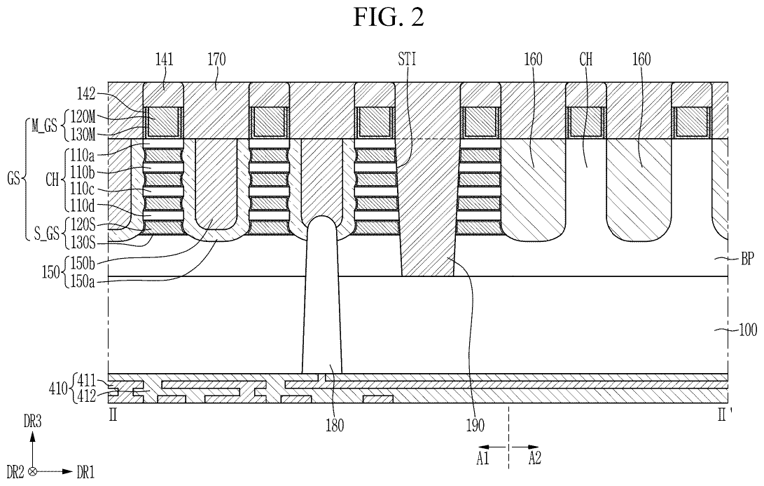

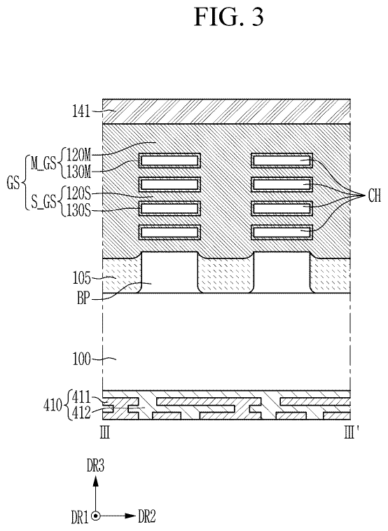

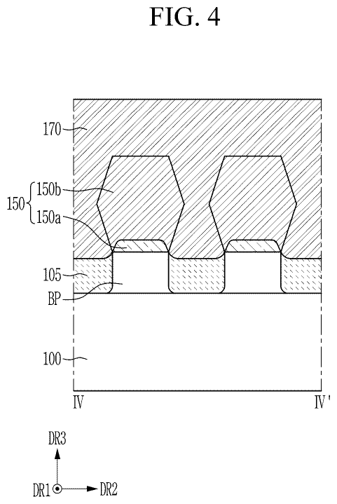

Hereinafter, a semiconductor device according to embodiments will be described with reference to drawings. Thus, for example, FIG. 1 is a top plan view showing a semiconductor device according to an embodiment. FIG. 2 to FIG. 4 are cross-sectional views showing the semiconductor device according to an embodiment of FIG. 1. Specifically, FIG. 2 is a cross-sectional view of a semiconductor device taken along line II-II′ of FIG. 1, and FIG. 3 is a cross-sectional view of a semiconductor device taken along line III-III′ of FIG. 1. FIG. 4 is a cross-sectional view of a semiconductor device taken along line IV-IV′ of FIG. 1.

Referring to FIG. 1 to FIG. 4, a semiconductor device according to an embodiment may include a substrate 100, a lower pattern BP located on the substrate 100, channel layers CH located on the lower pattern BP, gate structures GS and source/drain patterns 150, source/drain regions 160, and an interlayer insulating layer 170. As shown in FIG. 1 and FIG. 2, the substrate 100 may include a first region A1 and a second region A2. As will be separately explained below, the first region A1 may include the channel layer including a plurality of nanosheets, and the second region A2 may not include a plurality of nanosheets. The first region A1 may include gate-all-around (GAA), multi-bridge-channel field effect transistor (MBCFET™), or the like, including nanowires or nanosheets. The second region A2 may be a region where a passive element is located.

In an embodiment, the substrate 100 may be an insulating substrate. The substrate 100 may include oxide, nitride, nitride oxide or a combination thereof. For example, the substrate 100 may include silicon nitride (SiNx). Although the substrate 100 is illustrated as a single layer, it is merely for better understanding and ease of description, and is not limited thereto.

A first surface and a second surface of the substrate 100 may be on a plane parallel to a first direction DR1 and a second direction DR2 crossing the first direction DR1, respectively. For example, the first surface of the substrate 100 may be an upper surface, and the second surface may be a lower surface. An upper surface of the substrate 100 may be a surface opposite to a lower surface of the substrate 100 in a third direction DR3. The third direction DR3 may be a direction perpendicular to the first direction DR1 and the second direction DR2. The lower surface of the substrate 100 may be referred to a back side of the substrate 100. In some embodiments, the logic circuit of the cell region may be implemented on the upper surface of the substrate 100.

As shown in FIG. 1 and FIG. 2, a semiconductor device according to the present embodiment may include the lower patterns BP located on the substrate 100. The lower patterns BP may be portions protruding from the first surface of the substrate 100 in the third direction DR3. As shown, the lower patterns BP may extend in the first direction DR1. The lower patterns BP may be arranged on the first surface of the substrate 100, to be spaced apart in the second direction DR2. The source/drain patterns 150 and the source/drain regions 160 described later may be located on the lower patterns BP. The source/drain patterns 150 and the source/drain regions 160 may be arranged to be spaced apart in the first direction DR1 on each of the lower patterns BP.

The lower patterns BP may include silicon (Si) or germanium (Ge), which is an elemental semiconductor material. Alternatively, the lower patterns BP may include a compound semiconductor. For example, the lower patterns BP may include a group IV-IV compound semiconductor or a group III-V compound semiconductor. The group IV-IV compound semiconductor may be, for example, a binary compound, or a ternary compound including carbon (C), silicon (Si), germanium (Ge), tin (Sn), or a combination thereof. The group III-V compound semiconductor may be, for example, a binary compound, a ternary compound, or a quaternary compound formed by combining a group III element sch as aluminum (Al), gallium (Ga), indium (In), or a combination thereof, and a group V element such as phosphorus (P), arsenic (As), antimony (Sb), or a combination thereof. For example, the lower pattern BP may include silicon (Si).

As shown in FIG. 2 to FIG. 4, the channel layers CH may be located on the lower pattern BP. The channel layers CH may be arranged to be spaced apart in the first direction DR1, on the substrate 100 and/or the lower pattern BP. In the first region A1, each of the channel layers CH may include a plurality of semiconductor layers 110a, 110b, 110c, and 110d arranged to be spaced apart from each other in the third direction DR3. For example, each of the plurality of semiconductor layers 110a, 110b, 110c, and 110d may have a sheet shape. Each semiconductor layer may be a nanosheet with a thickness of several nanometers along the third direction DR3.

The channel layer CH may provide a passage through which the current may flow between the source/drain patterns 150 and the source/drain regions 160, which will be described later. Referring to FIG. 2 to FIG. 4, the channel layer CH may be disposed between the source/drain patterns 150, and connect the source/drain patterns 150. The channel layer CH may penetrate a portion of the gate structure GS, in the direction (e.g., the first direction DR1) crossing the direction in which the gate structure GS described later extends. FIG. 2 and FIG. 4 illustrate that, in each of the channel layers CH of the first region A1, four semiconductor layers 110a, 110b, 110c, and 110d are arranged to be spaced apart in the third direction DR3, but it is not limited thereto, and the number of stacks of the semiconductor layers 110a, 110b, 110c, and 110d included in one channel layer CH may be variously changed.

The channel layers CH may include a semiconductor material. For example, the channel layers CH may include a group IV semiconductor such as Si and Ge, a group III-V compound semiconductor, a group II-VI compound semiconductor, or the like. In an embodiment, the lower pattern BP may be located in a lower portion of the channel layer CH. Specifically, the lower pattern BP may be located between the substrate 100 and the sub-gate structure S_GS located lowermost among a plurality of sub-gate structures S_GS described later. An upper surface of the lower pattern BP may be in contact with a lower surface of the sub-gate structure S_GS located lowermost among the plurality of sub-gate structures S_GS.

A semiconductor device according to an embodiment may further include a field insulation layer 105 located on the substrate 100. The field insulation layer 105 may be located on the lower pattern BP. The field insulation layer 105 may located on a side surface of the lower pattern BP. The field insulation layer 105 may not be located on the upper surface of the lower pattern BP. The field insulation layer 105 may entirely cover the side surface of the lower pattern BP. Unlike what is shown, the field insulation layer 105 may cover a portion of the side surface of the lower pattern BP. In such a case, a portion of the lower pattern BP may protrude in the third direction DR3 from an upper surface of the field insulation layer 105. The field insulation layer 105 may include, for example, oxide, nitride, nitride oxide or a combination thereof. The field insulation layer 105 is illustrated as a single layer, but it is merely for better understanding and ease of description, and is not limited thereto.

The gate structure GS may be located on the substrate 100. The lower pattern BP or the field insulation layer 105 may be located between the gate structure GS and the substrate 100. On the substrate 100, the gate structure GS may extend in a direction different from the direction in which the lower pattern BP extends. For example, on the substrate 100, the gate structure GS may extend in the direction (e.g., the second direction DR2) crossing the direction in which the lower pattern BP extends. The gate structure GS may be located on the substrate 100. The gate structures GS may be arranged to be spaced apart from each other in the first direction DR1. The gate structure GS may include the sub-gate structure S_GS and main gate structure M_GS. The sub-gate structure S_GS may be located on the substrate 100, and the main gate structure M_GS may be located on the sub-gate structure S_GS.

Each of the sub-gate structures S_GS may be formed of multiple layers. For example, each of the sub-gate structures S_GS may include a sub-gate electrode 120S and a sub-gate insulation layer 130S. The sub-gate structures S_GS and the semiconductor layers 110a, 110b, 110c, and 110d may be alternately stacked in the third direction DR3. FIG. 2 and FIG. 3 illustrate that four sub-gate structures S_GS are arranged to be spaced apart in the third direction DR3, but the number of the sub-gate structures S_GS arranged to be spaced apart is not limited thereto. For example, the gate structure GS may include three sub-gate structures S_GS.

The sub-gate electrode 120S may formed on the lower pattern BP. The sub-gate electrode 120S may cross the lower pattern BP. The sub-gate electrode 120S may surround the plurality of semiconductor layers 110a, 110b, 110c, and 110d. At least a portion of the sub-gate electrode 120S may be located on the structure in which the sub-gate electrode 120S and the plurality of semiconductor layers 110a, 110b, 110c, and 110d are alternately stacked. Another portion of the sub-gate electrode 120S may be formed to cover both side surfaces of the structure in which the sub-gate electrode 120S and the plurality of semiconductor layers 110a, 110b, 110c, and 110d are alternately stacked. At this time, four surfaces of the plurality of semiconductor layers 110a, 110b, 110c, and 110d may be surrounded by the sub-gate electrode 120S.

The sub-gate electrode 120S may include at least one of a metal, a metal alloy, a conductive metal nitride, a metal silicide, a doped semiconductor material, a conductive metal oxide, and a conductive metal nitride oxide. The sub-gate electrode 120S may include, for example, at least one among titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto. The conductive metal oxide and the conductive metal nitride oxide may include, but are not limited to, oxidized forms of the materials described above.

The sub-gate insulation layer 130S may extend along the upper surface of the lower pattern BP. The sub-gate insulation layer 130S may be located along circumferences of the plurality of semiconductor layers 110a, 110b, 110c, and 110d. The sub-gate insulation layer 130S may directly contact the lower pattern BP, and the plurality of semiconductor layers 110a, 110b, 110c, and 110d. The sub-gate insulation layer 130S may be interposed between the plurality of semiconductor layers 110a, 110b, 110c, and 110d and the sub-gate electrode 120S. The sub-gate insulation layer 130S may include various insulating materials. Although not clearly illustrated in FIG. 2 to FIG. 4, a semiconductor device according to an embodiment may further include the sub-gate insulation layer 130S and an inner gate spacer located between the source/drain patterns 150 described later.

In an embodiment, the sub-gate insulation layer 130S is shown as a single layer, but is not limited thereto. For example, the sub-gate insulation layer 130S may be formed as a multilayer including silicon oxide (SiO₂) and a high dielectric constant material. At this time, high dielectric constant material may include a material having a dielectric constant higher than that of silicon oxide (SiO₂), such as hafnium oxide (HfO), aluminum oxide (AlO), or tantalum oxide (TaO).

The main gate structure M_GS may be located on the sub-gate structure S_GS and the plurality of semiconductor layers 110a, 110b, 110c, and 110d. The main gate structure M_GS may be located on an upper surface of the semiconductor layer 110a located uppermost among the plurality of semiconductor layers 110a, 110b, 110c, and 110d. The main gate structure M_GS may include a main gate electrode 120M and a main gate insulation layer 130M.

The main gate electrode 120M may be located on the sub-gate structure S_GS and the plurality of semiconductor layers 110a, 110b, 110c, and 110d. The main gate electrode 120M may include the same material as the sub-gate electrode 120S. For example, the main gate electrode 120M may include at least one of a metal, a metal alloy, a conductive metal nitride, a metal silicide, a doped semiconductor material, a conductive metal oxide, and a conductive metal nitride oxide.

As shown, the main gate insulation layer 130M may extend along a side surface of the main gate electrode 120M. The main gate insulation layer 130M may extend along a side surface of a gate spacer 142 described hereinbelow, and the main gate insulation layer 130M may include various insulating materials.

In an embodiment, the main gate insulation layer 130M is shown as a single layer, but is not limited thereto. For example, the main gate insulation layer 130M may be formed as a multilayer including silicon oxide (SiO₂) and a high dielectric constant material. At this time, high dielectric constant material may include a material having a dielectric constant higher than that of silicon oxide (SiO₂), such as hafnium oxide (HfO), aluminum oxide (AlO), or tantalum oxide (TaO).

A semiconductor device according to an embodiment may further include a capping layer 141 and the gate spacer 142. The gate spacer 142 may located on the side surface of the main gate electrode 120M. The gate spacer 142 may not be disposed between the lower pattern BP and the plurality of semiconductor layers 110a, 110b, 110c, and 110d. The gate spacer 142 may not be disposed between the plurality of semiconductor layers 110a, 110b, 110c, and 110d that are adjacent in the third direction DR3. Although the gate spacer 142 are illustrated as single layers, it is merely for better understanding and ease of description, and it is not limited thereto.

The gate spacer 142 may include, for example, at least one among silicon nitride (SiN), silicon nitride oxide (SiON), silicon oxide (SiO₂), silicon carbonate nitride (SiOCN), silicon boronnitride (SiBN), silicon oxyboronitride (SiOBN), silicon oxycarbide (SiOC), and combination thereof.

The capping layer 141 may be located on the main gate structure M_GS and the gate spacer 142. An upper surface of the capping layer 141 may lie on the same plane as an upper surface of the interlayer insulating layer 170. Unlike what is shown, the capping layer 141 may be located between the gate spacer 142.

The capping layer 141 may include, for example, at least one among silicon nitride (SiN), silicon nitride oxide (SiON), silicon (Si) carbonitride (SiCN), silicon carbonate nitride (SiOCN), and combination thereof. The capping layer 141 may include a material having an etch selectivity with respect to the interlayer insulating layer 170.

In the first region A1, the source/drain patterns 150 may be located on the substrate 100. The lower pattern BP may be located between the source/drain patterns 150 and the substrate 100. Referring to FIG. 1 and FIG. 2, the source/drain patterns 150 may be arranged to be spaced apart along the first direction DR1, on the lower pattern BP. The channel layer CH and the gate structure GS may be located between the source/drain patterns 150. In other words, a plurality of source/drain patterns 150 and a plurality of channel layers CH may be alternately arranged along the first direction DR1 in which the lower pattern BP extends.

In an embodiment, the source/drain patterns 150 may also be arranged in the second direction DR2. Referring to FIG. 1 and FIG. 4, a plurality of lower patterns BP may be arranged to be spaced apart along the second direction DR2 on the substrate 100, and the source/drain patterns 150 may be located on each of the lower patterns BP. Accordingly, the source/drain patterns 150 may be arranged to be spaced apart from each other along the second direction DR2, by substantially the same distance as the distance by which the plurality of lower patterns BP are spaced apart from each other.

In the first region A1, the source/drain pattern 150 may be located on both sides of the channel layer CH or the sub-gate structure S_GS. Specifically, two source/drain patterns 150 located on one lower pattern BP may be arranged to be spaced apart in the direction (e.g., the first direction DR1) crossing the direction in which the gate structure GS extends, interposing the channel layer CH or the sub-gate structure S_GS. The source/drain pattern 150 may directly contact the channel layer CH or the sub-gate structure S_GS.

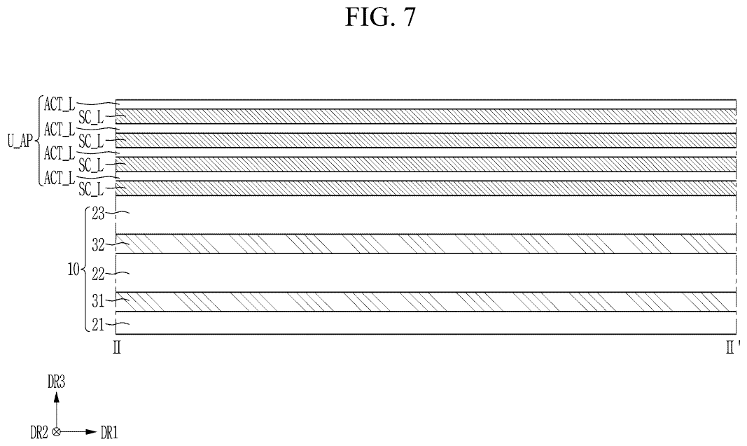

The source/drain pattern 150 may be formed as an epitaxial layer formed by selective epitaxial growth (SEG), in a recessed region of a portion of an active pattern ACT_L (see FIG. 7) and a sacrificial pattern SC_L (see FIG. 7) to be described later.

That is, the source/drain patterns 150 may fill the recessed region of the portion of the active pattern ACT_L (see FIG. 7) and the sacrificial pattern SC_L (see FIG. 7) to be described later.

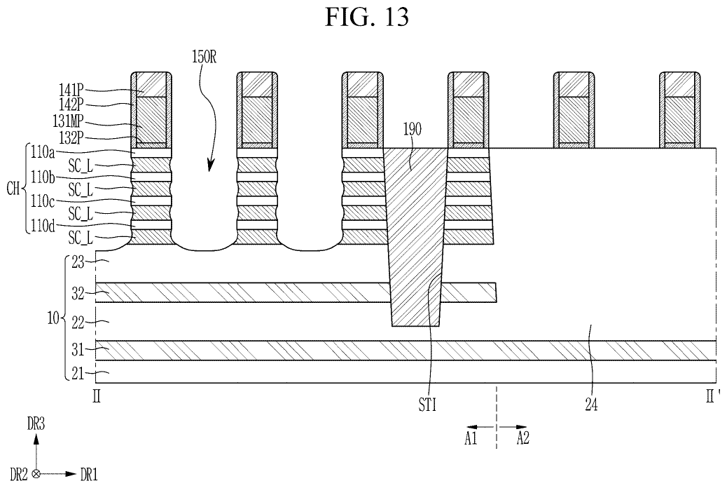

Each of the source/drain patterns 150 may include a liner layer 150a and a filling layer 150b. The liner layer 150a may be located on an outer side of the filling layer 150b. A side surface and a lower surface of the filling layer 150b may be surrounded by the liner layer 150a. The liner layer 150a may directly contact the sub-gate structure S_GS and the channel layer CH. That is, the liner layer 150a may be located along a surface profile of a source/drain recess 150R (see FIG. 13). The filling layer 150b may be located on the liner layer 150a. The filling layer 150b and the liner layer 150a may have upper surfaces of substantially the same height. The filling layer 150b may fill the interior of the source/drain recess 150R (see FIG. 13).

The source/drain pattern 150 may include a semiconductor material. The source/drain pattern 150 may include, for example, silicon or germanium. In addition, the source/drain pattern 150 may include a binary compound or a ternary compound that includes at least two or more among, for example, carbon (C), silicon (Si), germanium (Ge), and tin (Sn). For example, the source/drain pattern 150 may include silicon, silicon-germanium, germanium, silicon carbide, or the like, but is not limited thereto. In an embodiment, the liner layer 150a and the filling layer 150b may have different concentrations of silicon (Si) or germanium (Ge). For example, the concentration of silicon (Si) or germanium (Ge) included in the liner layer 150a may be lower than the concentration of silicon (Si) or germanium (Ge) included in the filling layer 150b.

In addition, in the second region A2, the source/drain region 160 may be located on both sides of the channel layer CH. Unlike the source/drain pattern 150 of the first region A1, the source/drain region 160 of the second region A2 may be a doped region of the lower pattern BP. That is, the source/drain region 160 located in the second region A2 may be formed by doping the lower pattern BP without a separate recess process.

A semiconductor device according to an embodiment may further include the interlayer insulating layer 170. The interlayer insulating layer 170 may be located on the side surface of the gate spacer 142, a side surface of the capping layer 141, an upper surface of the source/drain pattern 150 and the source/drain region 160. The interlayer insulating layer 170 may cover at least a portion of side surface of the source/drain pattern 150. The interlayer insulating layer 170 may cover the field insulation layer 105. The interlayer insulating layer 170 may not cover the upper surface of the capping layer 141.

The interlayer insulating layer 170 may include, for example, at least one among silicon oxide (SiO₂), silicon nitride (SiN), silicon nitride oxide (SiON), and low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen Silazen), fluorosilicate glass (FSG), polyimide nanofoams such as polypropylene oxide, carbon-doped silicon oxide (CDO), organosilicate glass (OSG), SiLK, amorphous fluorinated carbon, silica aerogels, silica xerogels, mesoporous silica or a combination thereof, but is not limited thereto. In an embodiment, the interlayer insulating layer 170 may include an insulating material having an etch selectivity with respect to the field insulation layer 105. However, it is not limited thereto, and in another embodiment, the interlayer insulating layer 170 may include the same insulating material as the field insulation layer 105.

In addition, as shown in FIG. 2, a separation insulation layer 190 may be located within a device isolation trench STI. The separation insulation layer 190 may located on an inner sidewall and a lower surface of the device isolation trench STI. The separation insulation layer 190 may include the same material as the interlayer insulating layer 170. In an embodiment, a boundary between the separation insulation layer 190 and the interlayer insulating layer 170 may not be visible.

Although not clearly shown in FIG. 2 to FIG. 4, a semiconductor device according to an embodiment may further include an etch stop layer located between the interlayer insulating layer 170 and the field insulation layer 105 and/or between the interlayer insulating layer 170 and the gate structure GS. The etch stop layer may include an insulating material different from the insulating material included in the interlayer insulating layer 170. The etch stop layer may include a material having an etch selectivity with respect to the interlayer insulating layer 170. The etch stop layer may include, for example, at least one among silicon nitride (SiN), silicon nitride oxide (SiON), silicon carbonate nitride (SiOCN), silicon boronnitride (SiBN), silicon oxyboronitride (SiOBN), silicon oxycarbide (SiOC), and a combination thereof. In the process of selectively etching the interlayer insulating layer 170, the etch stop layer may protect the field insulation layer 105 or the gate structure GS from being etched by certain etching materials.

Referring to FIG. 2, a penetration electrode 180 that penetrates the substrate 100 and the lower pattern BP may be further included. The penetration electrode 180 may electrically connect at least one of the source/drain patterns 150 and a lower wire structure 410 described later.

The penetration electrode 180 may penetrate the substrate 100 and the lower pattern BP in the third direction DR3. The penetration electrode 180 may intrude into the source/drain pattern 150. Accordingly, the penetration electrode 180 may be in contact with at least a partial region of the source/drain pattern 150. Referring to FIG. 2, in the region where the penetration electrode 180 intrudes into the source/drain pattern 150, although it is illustrated that the penetration electrode 180 is in contact with the liner layer 150a and the filling layer 150b of the source/drain pattern 150, the penetration electrode 180 may be in contact with only the liner layer 150a of the source/drain pattern 150. Although not shown, a silicide layer may be located along at least a portion of upper surface or at least a portion of side surface of the penetration electrode 180. The silicide layer may be a metal silicide layer. For example, the silicide layer may include at least one of tungsten silicide (WSi), nickel silicide (NiSi), and/or titanium silicide (TiSi).

The penetration electrode 180 may also be in contact with the lower pattern BP and/or the substrate 100. Referring to FIG. 2, the penetration electrode 180 may have a side surface that is in contact with the lower pattern BP and/or the substrate 100, in a region that does not overlap with the source/drain pattern 150 in the horizontal direction. Although not clearly shown in FIG. 2, between the penetration electrode 180 and the substrate 100, or between the penetration electrode 180 and the lower pattern BP, an insulation pattern may be further located along a side surface profile of the penetration electrode 180.

In an embodiment, the width of the penetration electrode 180 along the horizontal direction may gradually narrows as it goes from the lower surface in contact with the lower wire structure 410 described later toward the source/drain pattern 150. The penetration electrode 180 may include at least one of a metal, a metal alloy, a conductive metal nitride, a conductive metal carbide, a conductive metal oxide, a conductive metal carbonitride, and a 2-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CoN), and platinum nitride (PtN).

The lower wire structure 410 may be located on the lower surface of the substrate 100. An upper surface of the lower wire structure 410 may be in partial contact with a lower surface of the penetration electrode 180. The lower wire structure 410 may include lower conductive patterns 411 and a lower wire insulation layer 412. The lower conductive patterns 411 may include lower wires arranged to be spaced apart in the third direction DR3 and lower wire vias connecting two lower wires. The lower conductive patterns 411 may be located between the lower wire insulation layer 412. The lower wire insulation layer 412 may surround the lower conductive patterns 411. That is, the lower wire insulation layer 412 may cover the lower conductive patterns 411, and the lower conductive patterns 411 may be located within the lower wire insulation layer 412.

The lower conductive patterns 411 may include a metal (e.g., copper). The lower wire insulation layer 412 may include, for example, at least one of silicon oxide (SiO₂), silicon nitride (SiN), silicon nitride oxide (SiON), or low-k dielectric layers.

In an embodiment, the electrical signal, power source voltage, or the like, supplied from the outside may be provided to the source/drain patterns 150, through the lower wire structure 410 and the penetration electrode 180 connected thereto.

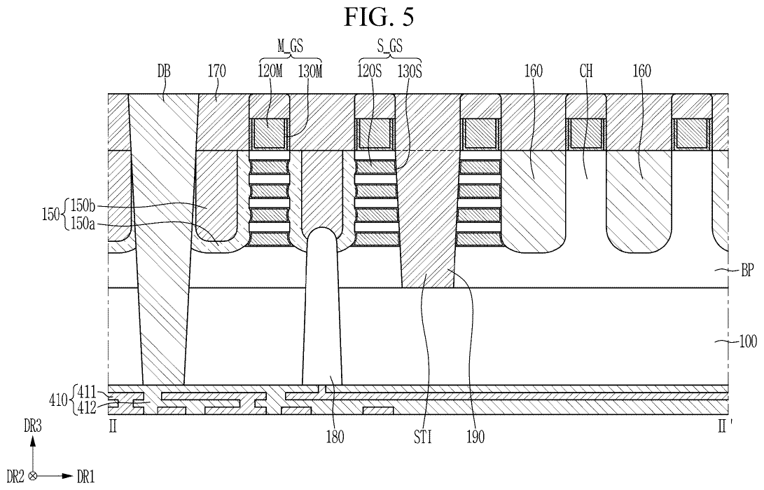

Although not shown in FIG. 1 to FIG. 4, a semiconductor device according to another embodiment may further include a separation structure DB. FIG. 5 shows the same cross-section as FIG. 2 according to another embodiment. Referring to FIG. 5, a display device according to the present embodiment is the same as the embodiment of FIG. 2, except that the separation structure DB is further included. Detailed description of the same components will be omitted. Referring to FIG. 5, the separation structure DB in a semiconductor device according to the present embodiment may be located in a region where the gate structure GS of FIG. 2 was located. A thickness of the separation structure DB in the third direction DR3 may be thicker than a thickness of the device isolation trench STI in the third direction DR3. However, this is merely an example, and the present disclosure is not limited thereto. An interior of the separation structure DB may be filled with at least one of silicon oxide (SiO₂), silicon nitride (SiN), silicon nitride oxide (SiON), and low dielectric constant material.

As shown in FIG. 2 and FIG. 5, the penetration electrode 180 in a semiconductor device according to the present embodiment may penetrate the substrate 100 and the lower pattern BP, to be connected to the source/drain pattern 150. At this time, when the thicknesses of the substrate 100 and the lower pattern BP are not uniform, it may be difficult to form the penetration electrode 180 at a precise position when forming the penetration electrode 180.

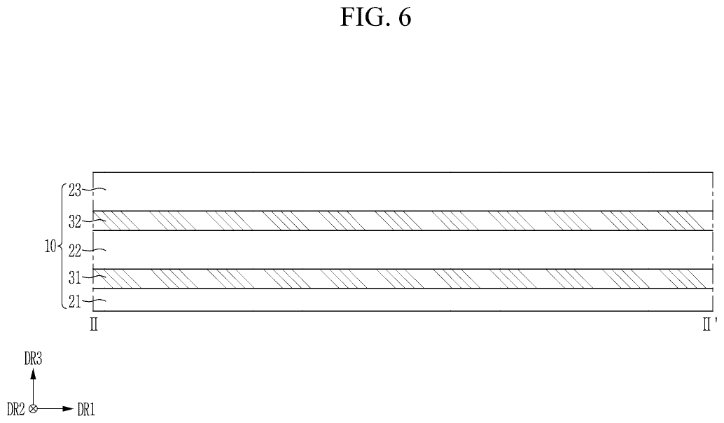

Therefore, a manufacturing method of a semiconductor device according to the present embodiment is characterized in that, when forming the lower pattern BP, etch-stop layers 31 and 32 (see FIG. 6) of a dual layer structure are formed underneath, thereby reducing the process distribution of the lower pattern BP and making the thickness uniform. Hereinafter, a manufacturing method of a semiconductor device according to the present embodiment will be described.

FIG. 6 to FIG. 23 illustrate a manufacturing method of a semiconductor device according to the present embodiment. FIG. 6 to FIG. 23 illustrate a manufacturing method of a semiconductor device with respect to the same cross-section as FIG. 2.

Referring to FIG. 6, a substrate laminate 10 may be formed to include a first base layer 21, a first etch-stop layer 31, a second base layer 22, a second etch-stop layer 32 and a third base layer 23.

The first base layer 21, the second base layer 22 and the third base layer 23 may include silicon (Si). The first etch-stop layer 31 and the second etch-stop layer 32 may include silicon germanium. In an embodiment, a thickness of the first etch-stop layer 31 and the second etch-stop layer 32 may be thinner than the thicknesses of the first base layer 21, the second base layer 22, and the third base layer 23. In an embodiment, the thickness of the first etch-stop layer 31 and the second etch-stop layer 32 may be 150 Å to 250 Å. A thickness of the second base layer 22 and the third base layer 23 may be 250 Å to 600 Å. A thickness of the first base layer 21 may be tens of μm to hundreds of μm. For example, the thickness of the first base layer 21 may be 500 μm to 1000 μm.

Subsequently, referring to FIG. 7, an upper pattern structure U_AP may be formed on the substrate laminate 10. The upper pattern structure U_AP may be located on the substrate laminate 10. The upper pattern structure U_AP may include the sacrificial pattern SC_L and the active pattern ACT_L alternately stacked on the lower pattern BP. For example, the sacrificial pattern SC_L may include silicon germanium (SiGe). The active pattern ACT_L may include silicon (Si).

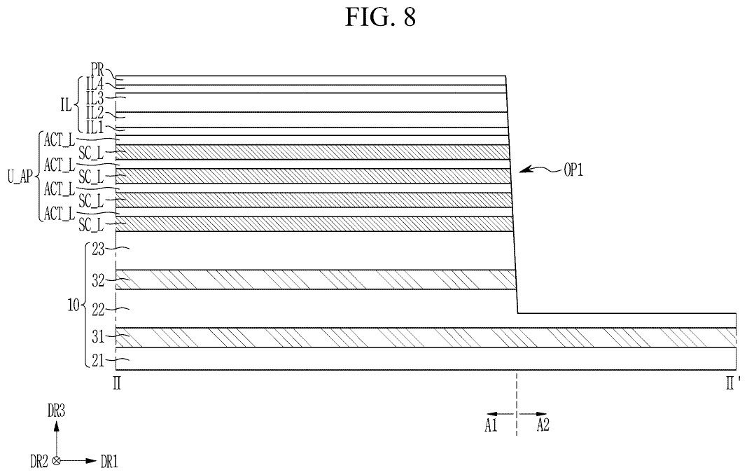

Subsequently, referring to FIG. 8, an opening OP1 may be formed by locating a photoresist PR on the upper pattern structure U_AP and etching a portion corresponding to the second region A2. A multi-layered insulation layer IL may be located between the photoresist PR and the upper pattern structure U_AP. For example, a first insulation layer IL1 to a fourth insulation layer IL4 may be located. The first insulation layer IL1 may include SiN, and the second insulation layer IL2 may include silicon oxide, and the third insulation layer IL3 may include SOH, and the fourth insulation layer IL4 may include pSION. However, this is merely an example, and the present disclosure is not limited thereto.

An area of the opening OP1 formed in the present step may be the same as an area of the second region A2 shown in FIG. 2. The etching in the present step may be performed to the upper pattern structure U_AP, the third base layer 23, the second etch-stop layer 32, and the second base layer 22. That is, as shown in FIG. 8, the opening OP1 may be formed within the third base layer 23, the second etch-stop layer 32, the second base layer 22, and the first etch-stop layer 31 may not be etched.

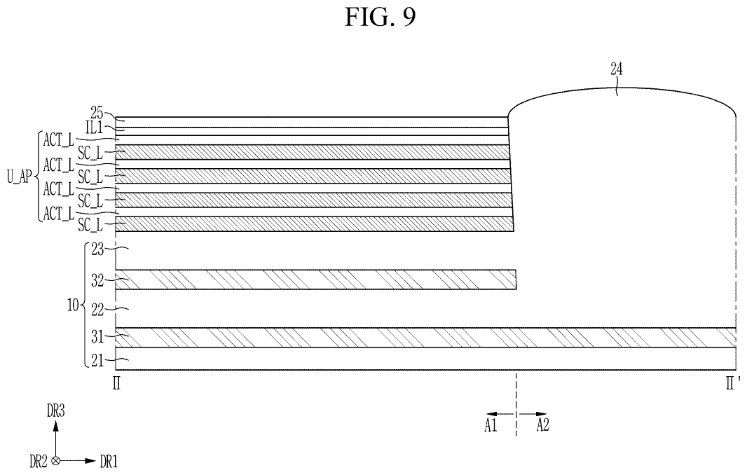

Subsequently, referring to FIG. 9, a monocrystalline silicon layer 24 may be grown within the opening OP1. Accordingly, the first etch-stop layer 31 may not be located in the region where the opening OP1 was located. This is because, in the case of the passive element located in the second region A2, when a layer including silicon germanium (SiGe) exists under the channel, degradation of performance due to recombination may occur. In the monocrystalline silicon layer 24 growing step of the present step, a polycrystalline silicon layer 25 may be formed on the first insulation layer IL1, as a by-product. The monocrystalline silicon layer 24 formed in the present step includes silicon, and a boundary with respect to the second base layer 22 and the third base layer 23 may not be visible.

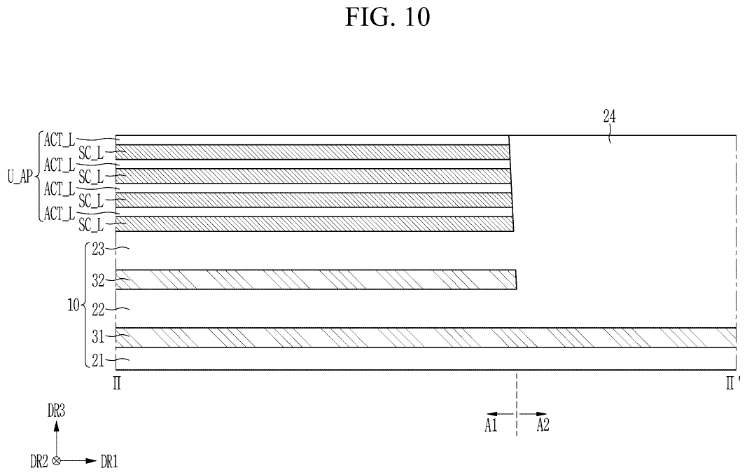

Subsequently, referring to FIG. 10, a chemical mechanical polishing (CMP) process may be performed in order to remove a step between the first region A1 and silicon of the crystal-grown second region A2 and to remove the polycrystalline silicon layer 25 formed on the first region A1 as a by-product in the step of FIG. 9. At this time, the CMP process may be performed by using the first insulation layer IL1 as the etch stop layer. Subsequently, an etch back may be performed to remove the step, and to remove any film component remaining on the upper pattern structure U_AP. FIG. 10 illustrates an upper surface of the substrate laminate 10 of the second region A2 to be flat, but a step may be formed during the process of etching back.

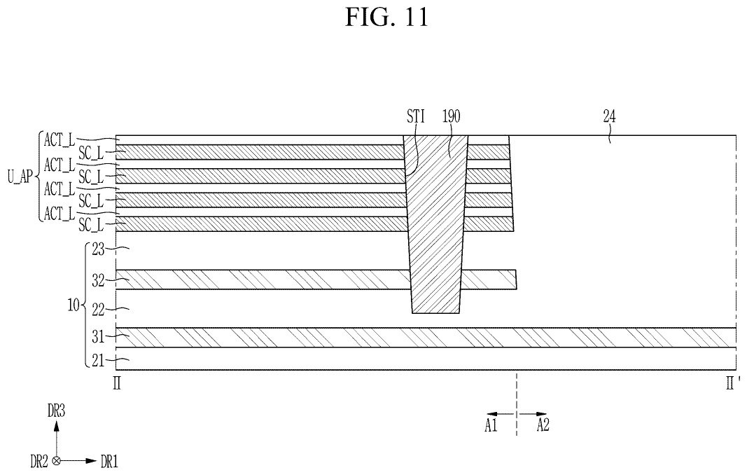

Subsequently, referring to FIG. 11, the device isolation trench STI may be formed by etching a portion of the substrate laminate 10 and the upper pattern structure U_AP. The device isolation trench STI may penetrate the upper pattern structure U_AP. The device isolation trench STI may recess at least a portion of the substrate laminate 10. As shown in FIG. 11, the device isolation trench STI may be formed in the third base layer 23, the second etch-stop layer 32 and the second base layer 22. The separation insulation layer 190 may be filled within the formed device isolation trench STI. The material of the separation insulation layer 190 is as described above. That is, the separation insulation layer 190 may include at least one of silicon oxide (SiO₂), silicon nitride (SiN), silicon nitride oxide (SiON), and low dielectric constant material. As described above, the separation insulation layer 190 may include the same material as the interlayer insulating layer 170 subsequently formed.

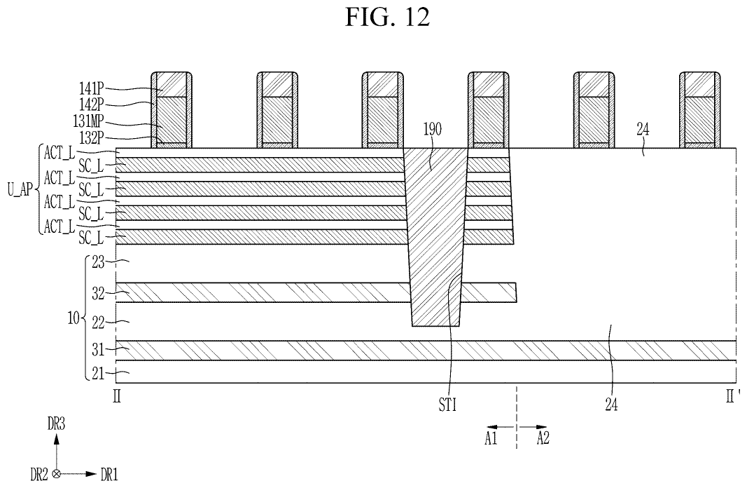

Subsequently, referring to FIG. 12, a preliminary gate insulation layer 132P, a preliminary main gate electrode 131MP, and a preliminary capping layer 141P may be formed on the upper pattern structure U_AP. The preliminary gate insulation layer 132P may include, for example, silicon oxide (SiOx), but is not limited thereto. The preliminary main gate electrode 131MP may include, for example, polysilicon, but is not limited thereto. The preliminary capping layer 141P may include, for example, silicon nitride, but is not limited thereto. A preliminary gate spacer 142P may be formed on both side surfaces of the preliminary main gate electrode 131MP.

Subsequently, as shown in the FIG. 13, by using the preliminary capping layer 141P and the preliminary gate spacer 142P as the mask, the source/drain recess 150R may be formed by etching at least a portion of the upper pattern structure U_AP. As the source/drain recess 150R is formed, at least a portion of the lower pattern BP may be etched. A portion of the source/drain recess 150R may be formed within the substrate laminate 10.

However, as shown in FIG. 13, the source/drain recess 150R may be formed in the first region A1, and may not be formed in the second region A2. Advantageously, as the source/drain recess 150R is formed, the active pattern ACT_L may be separated to thereby form the channel layers CH. The channel layers CH may be located on both sides of the source/drain recess 150R, respectively. The plurality of semiconductor layers 110a, 110b, 110c, and 110d and the sacrificial patterns SC_L included in the channel layer CH may be alternately stacked in the third direction DR3. At this time, the length of each of the plurality of semiconductor layers 110a, 110b, 110c, and 110d may be different, and may be the same.

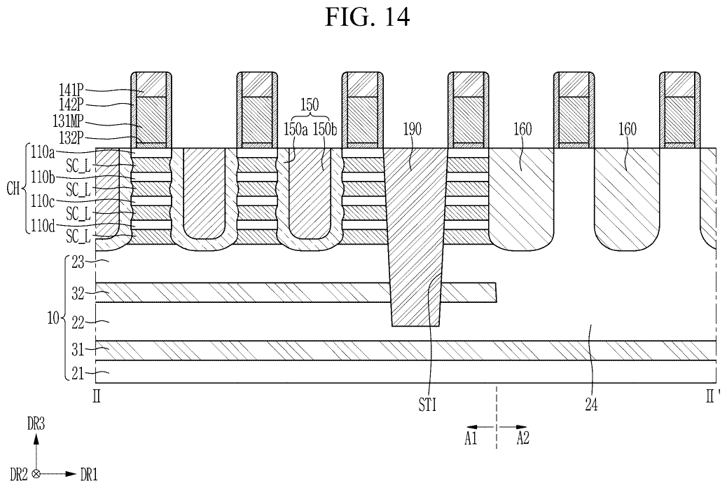

Subsequently, as shown in FIG. 14, the source/drain pattern 150 may be formed within the source/drain recess 150R of the first region A1. The source/drain pattern 150 may formed on the substrate laminate 10. The source/drain pattern 150 may be formed by using the epitaxial growth method. At this time, an inner wall of the source/drain recess 150R may be used as a seed. The source/drain pattern 150 may directly contact the substrate laminate 10. The source/drain pattern 150 may directly contact the semiconductor layers 110a, 110b, 110c, and 110d and the sacrificial patterns SC_L. The source/drain pattern 150 may include silicon (Si), germanium (Ge) or silicon germanium (SiGe). The source/drain pattern 150 may be formed of many regions having different concentrations.

For example, referring to FIG. 14, the source/drain pattern 150 may include the liner layer 150a and the filling layer 150b. The liner layer 150a and the filling layer 150b may be sequentially formed. That is, first, the liner layer 150a may be formed along a side surface and a lower surface of the source/drain recess 150R, and the filling layers 150b may be formed on each of the liner layers 150a. The liner layer 150a and the filling layers 150b may be formed by using the epitaxial growth method, respectively. The liner layer 150a and the filling layer 150b may include a semiconductor material. For example, the liner layer 150a and the filling layer 150b may include silicon (Si) or germanium (Ge), which is an elemental semiconductor material. In an embodiment, the liner layer 150a and the filling layer 150b may have different concentrations of silicon (Si) or germanium (Ge). For example, the concentration of silicon (Si) or germanium (Ge) included in the liner layer 150a may be lower than the concentration of silicon (Si) or germanium (Ge) included in the filling layer 150b. In addition, the source/drain region 160 may be formed by doping the substrate laminate 10 of the second region A2.

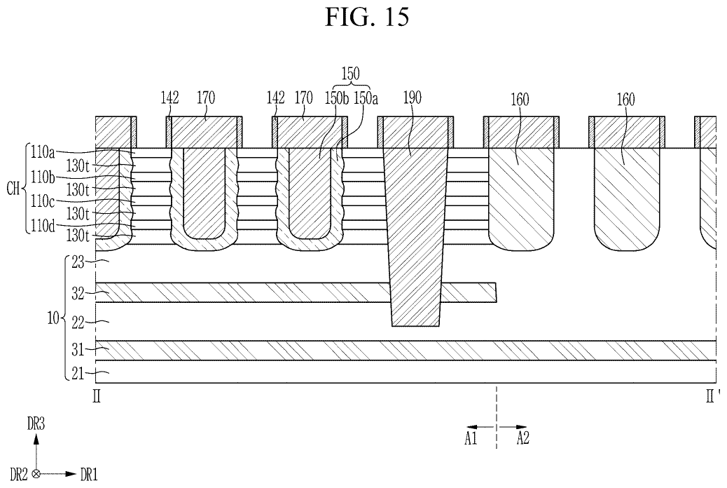

Subsequently, referring to FIG. 15, the interlayer insulating layer 170 may be formed on the source/drain pattern 150 and the source/drain region 160. Subsequently, by removing a portion of a first interlayer insulating layer 170 and the preliminary capping layer 141P, an upper surface of the preliminary main gate electrode 131MP may be exposed. At this time, a portion of the preliminary gate spacer 142P may be removed together, such that the gate spacer 142 may be formed. Thereafter, by removing remaining preliminary gate insulation layers 132P and the preliminary main gate electrodes 131MP, the upper pattern structure U_AP between the gate spacer 142 in the first region A1 may be exposed. Subsequently, a gate trench 130t may be formed by removing the sacrificial pattern SC_L between the channel layer CH and the lower pattern BP.

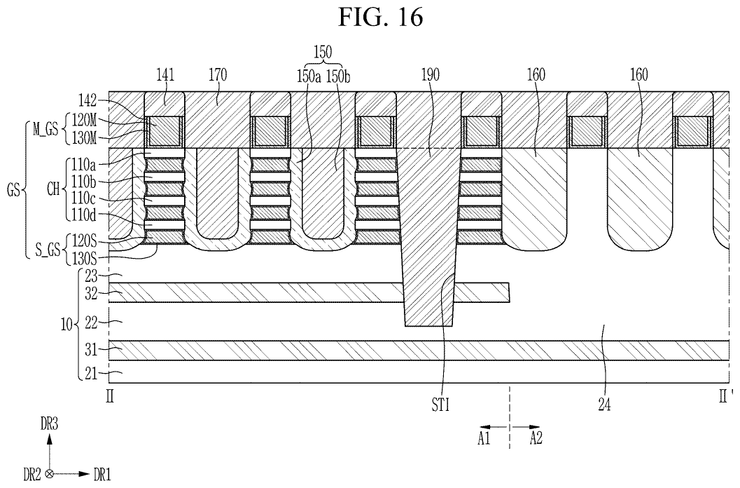

Subsequently, as shown in the FIG. 16, the sub-gate insulation layer 130S and the sub-gate electrode 120S may be sequentially formed within the gate trench 130t. In addition, the main gate insulation layer 130M, the main gate electrode 120M, and the capping layer 141 may be sequentially formed. The sub-gate insulation layer 130S and the main gate insulation layer 130M may be simultaneously formed in the same process. The sub-gate electrode 120S and the main gate electrode 120M may be simultaneously formed in the same process.

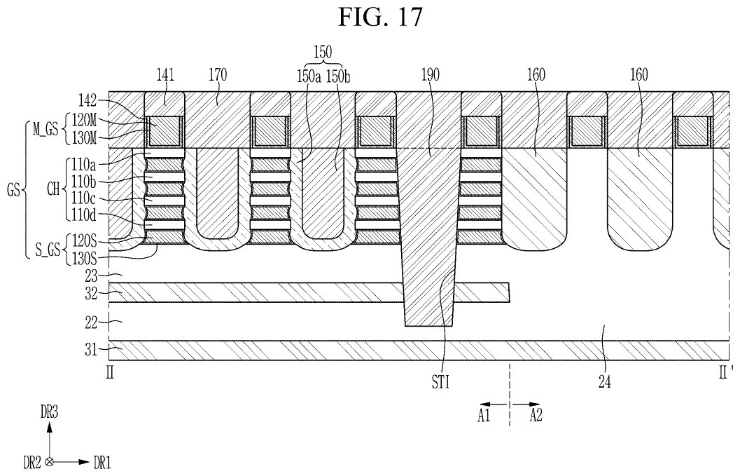

Subsequently, as shown in FIG. 17, the first base layer 21 of the substrate laminate 10 may be removed. At this time, the first base layer 21 may remove the thickness of the first base layer 21 through the CMP process until its thickness becomes about several μm, for example, 5 μm level, and then remove a remaining portion through wet etching. Since the first base layer 21 includes silicon and the first etch-stop layer 31 includes silicon germanium, the first base layer 21 may be removed by using a material having an etch selectivity with respect to silicon. However, this method is merely an example, and the present disclosure is not limited thereto.

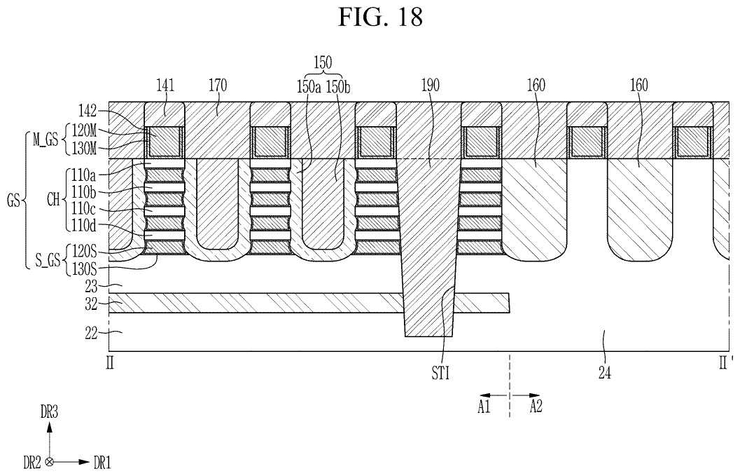

Subsequently, as shown in FIG. 18, the first etch-stop layer 31 may be removed. At this time, the first etch-stop layer may be removed by wet etching. Since the first etch-stop layer 31 includes silicon germanium and the second base layer 22 includes silicon, the first etch-stop layer 31 may be selectively removed by using a material having an etch selectivity with respect to silicon germanium.

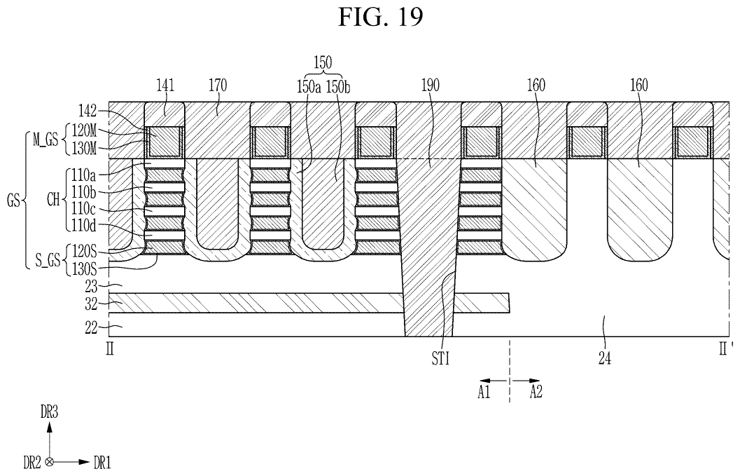

Subsequently, as shown in FIG. 19, the second base layer 22 and the monocrystalline silicon layer 24 may be partially removed through the CMP process. At this time, the CMP process may be performed by using the device isolation trench STI as the etch stop layer. That is, in the present step, the second base layer 22 located on the lower surface of the device isolation trench STI may be removed.

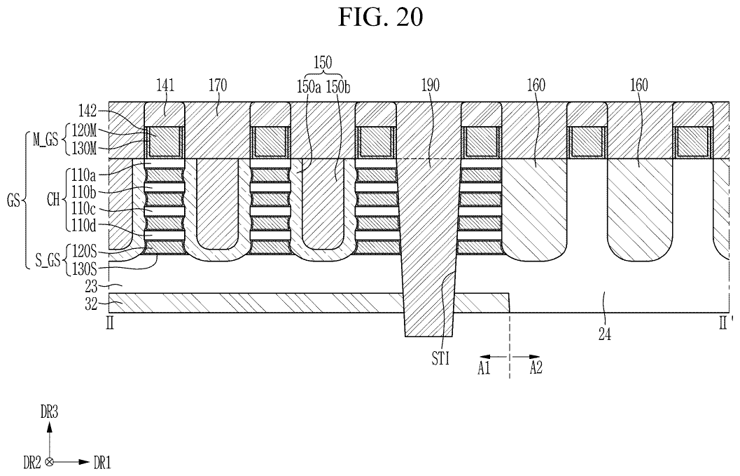

Subsequently, as shown in FIG. 20, the second base layer 22 and the monocrystalline silicon layer 24 may be removed. At this time, the removal of the second base layer 22 and the monocrystalline silicon layer 24 may be formed by dry etching. In the present step, the second base layer 22 and the monocrystalline silicon layer 24 may be removed. However, the separation insulation layer 190 filling the device isolation trench STI and the device isolation trench STI may not be removed. Accordingly, as shown in FIG. 20, the device isolation trench STI may be located to protrude.

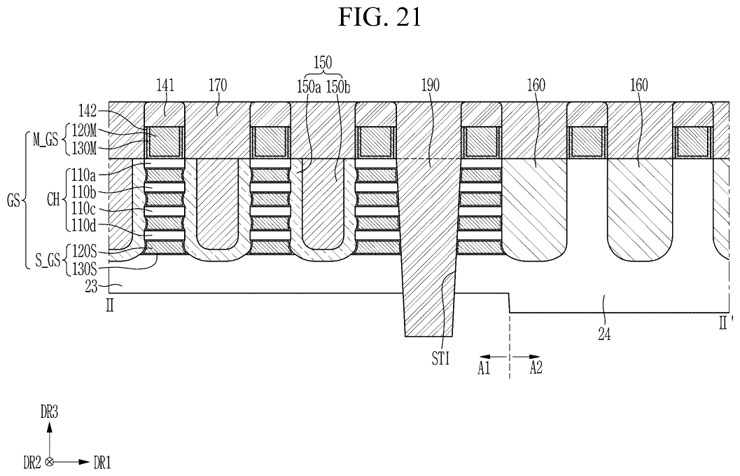

Subsequently, referring to FIG. 21, the second etch-stop layer 32 may be removed. At this time, the second etch-stop layer 32 may be removed by wet etching. Since the second etch-stop layer 32 includes silicon germanium and the third base layer 23 includes silicon, the second etch-stop layer 32 may be removed by using a material having an etch selectivity with respect to silicon germanium. In the present step, the separation insulation layer 190 filling the device isolation trench STI and the device isolation trench STI may not be etched. Accordingly, as shown in FIG. 21, the device isolation trench STI may be located to protrude. In addition, a step may be formed between the second region A2 where the second etch-stop layer 32 was not located and the first region A1 where the second etch-stop layer 32 was located.

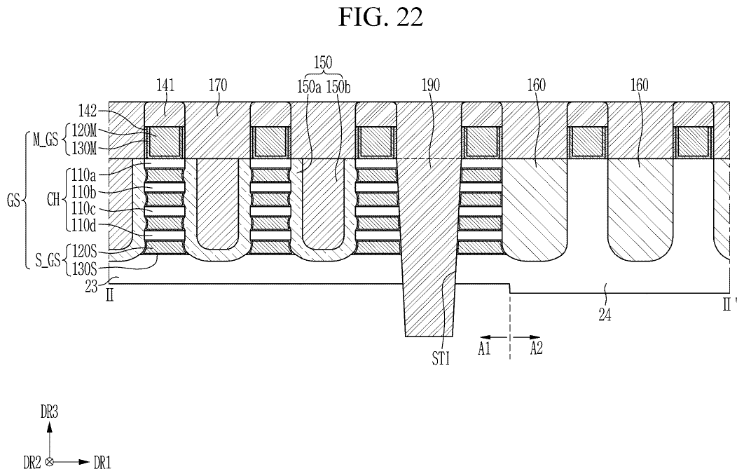

Subsequently, referring to FIG. 22, the third base layer 23 and the monocrystalline silicon layer 24 may be etched. At this time, etching of the third base layer 23 may be formed by dry etching. The etching of the third base layer 23 and the monocrystalline silicon layer 24 may be performed in the range for satisfying a target thickness. For example, the etching may be performed such that the third base layer 23 and the monocrystalline silicon layer 24 may have a final thickness of 20 nm to 30 nm. However, since a step was formed between the third base layer 23 of the first region A1 and the monocrystalline silicon layer 24 of the second region A2 in the previous step, thicknesses of the third base layer 23 and the monocrystalline silicon layer 24 may not be the same in the first region A1 and the second region A2 even after the dry etching of the present step, by which a step may still exist. However, after the etching of FIG. 22, the step between the third base layer 23 and the monocrystalline silicon layer 24 in the first region A1 and the second region A2 may be lower than the step between the third base layer 23 and the monocrystalline silicon layer 24 between the first region A1 and the second region A2 of FIG. 21. The etched third base layer 23 and the monocrystalline silicon layer 24 may form the lower pattern BP of FIG. 2.

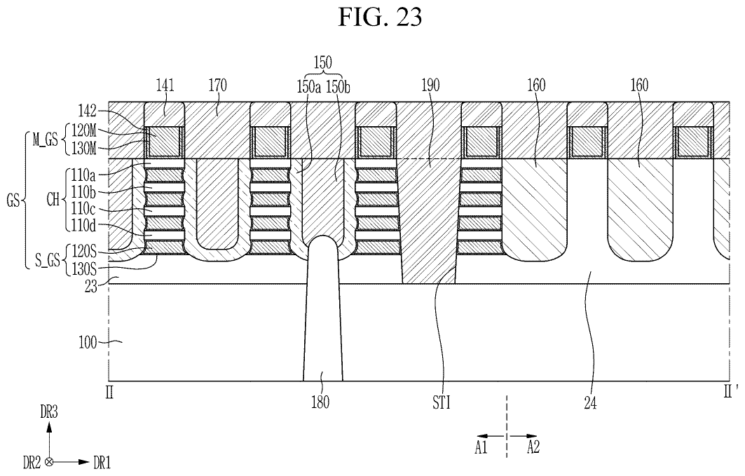

Subsequently, referring to FIG. 23, a lower surface of the third base layer 23 and the monocrystalline silicon layer 24 may be formed to be uniform through the CMP process, and after attaching the substrate 100, the penetration electrode 180 penetrating the substrate 100 and the third base layer 23 may be formed. The substrate 100 and the penetration electrode 180 may be the same as described above and redundant description will be omitted. Subsequently, by forming the lower wire structure 410 on the lower surface of the substrate 100, the semiconductor device as shown in FIG. 2 may be manufactured.

As described above, according to a manufacturing method of a semiconductor device according to the present embodiment, the substrate laminate 10 may include the first etch-stop layer 31 and the second etch-stop layer 32, and by stepwise etching the first etch-stop layer 31 and the second etch-stop layer 32, the substrate laminate 10 may be formed at a target thickness. In the step of etching each of the etch-stop layers 31 and 32, since the thickness distribution of the substrate laminate 10 etched by selective wet etching may decrease, the thickness distribution of the finally etched lower pattern BP may become uniform, compared to the case where only a single etch-stop layer is included or the etch-stop layer is not included.

That is, when the thick substrate is to be etched by a single process, according to the difference of etch-rate depending on regions, the thickness distribution may occur. However, according to a manufacturing method of a semiconductor device according to the present embodiment, the stepwise etching is performed by including the first etch-stop layer 31 and the second etch-stop layer 32, the thickness distribution of the finally etched substrate laminate 10 may be minimized. Accordingly, when forming the penetration electrode 180, the misalignment due to the thickness distribution of the lower pattern BP may be minimized, and the penetration electrode 180 and the source/drain pattern 150 may be stably contacted.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

1. A method of manufacturing a semiconductor device, comprising:
forming a substrate laminate comprising a first base layer, a first etch-stop layer including silicon germanium, a second base layer, a second etch-stop layer including silicon germanium, and a third base layer;
forming an opening in the substrate laminate by etching a partial region therein;
growing monocrystalline silicon within the opening;
forming a plurality of channel layers arranged on the substrate laminate to be spaced apart in a first direction parallel to a first surface of the substrate laminate, a plurality of gate structures extending in a second direction crossing the first direction, and source/drain regions located on both sides of each of the channel layers; and
removing the first base layer, the first etch-stop layer, the second base layer, and the second etch-stop layer.

2. The method of claim 1, wherein the first, second and third base layers respectively comprise silicon.

3. The method of claim 1, wherein the third base layer, the second etch-stop layer, and a portion of the second base layer are etched, but the first etch-stop layer is not etched, during said forming an opening in the substrate laminate.

4. The method of claim 1, wherein the etching the first etch-stop layer is performed by wet etching.

5. The method of claim 1, further comprising:
forming a device isolation trench in the substrate laminate; and
wherein a lower surface of the device isolation trench is located within the second base layer.

6. The method of claim 5, wherein, upon removing of the second base layer, the device isolation trench is not removed and located to protrude.

7. The method of claim 1, wherein, upon removing of the second etch-stop layer, a step is formed on a lower surface of the substrate laminate.

8. The method of claim 1, wherein, during the growing of the monocrystalline silicon in the opening, the substrate laminate is divided into a second region that overlaps with the grown monocrystalline silicon and a first region that does not overlap with the grown monocrystalline silicon, and a passive element is located in the second region.

9. The method of claim 8, wherein the channel layer of the first region comprises a plurality of nanosheets; wherein the first region comprises source/drain patterns located on both sides of the channel layer; and wherein the source/drain pattern is located within a recessed region of the substrate laminate.

10. The method of claim 8, wherein the channel layer of the second region is a single layer; wherein the second region comprises source/drain regions located on both sides of the channel layer; and wherein the source/drain region is formed by doping the substrate laminate.

11. The method of claim 9, further comprising:
decreasing a thickness of the third base layer; and
forming a penetration electrode that penetrates the third base layer and contacts the source/drain pattern.

12. A method of manufacturing a semiconductor device, comprising:
forming a substrate laminate comprising: a first region, which includes a first base layer, a first etch-stop layer, a second base layer, second etch-stop layer and a third base layer, and a second region, which includes the first base layer, the first etch-stop layer, the second base layer and the third base layer;
forming a plurality of channel layers arranged on the first region and the second region to be spaced apart in a first direction parallel to a first surface of the substrate laminate, and a plurality of gate structures extending in a second direction crossing the first direction;
forming source/drain patterns, which are located on both sides of each of the channel layers in the first region and located in a recess region of the substrate laminate;
forming source/drain regions, which are located on both sides of the each of the channel layers in the second region and are formed by doping the substrate laminate; and
etching the substrate laminate; and
wherein the first to the third base layer and the first etch-stop layer and the second etch-stop layer comprise different materials.

13. The method of claim 12, wherein the first base layer, the second base layer, and the third base layer comprise silicon.

14. The method of claim 13, wherein the first etch-stop layer and the second etch-stop layer comprise silicon germanium.

15. The method of claim 12, wherein the channel layer of the first region comprises a plurality of nanosheets; and wherein the channel layer of the second region is a single layer.

16. The method of claim 12, wherein a passive element is located in the second region.

17. The method of claim 12, wherein the etching the substrate laminate comprises removing the first base layer, the first etch-stop layer, the second base layer, and the second etch-stop layer.

18. A method of manufacturing a semiconductor device, comprising:
forming a substrate laminate comprising a first base layer, a first etch-stop layer, a second base layer, a second etch-stop layer, and a third base layer;
forming an opening by etching a partial region of the third base layer, the second etch-stop layer, and the second base layer of the substrate laminate;
growing monocrystalline silicon in the opening;
removing the first base layer, the first etch-stop layer, the second base layer, and the second etch-stop layer; and
decreasing a thickness of the third base layer;
wherein the first to the third base layer respectively comprise silicon, and the first etch-stop layer and the second etch-stop layer respectively comprise silicon germanium.

19. The method of claim 18,
wherein, during the growing of the monocrystalline silicon in the opening, the substrate laminate is divided into a second region that overlaps with the grown monocrystalline silicon and a first region that does not overlap with the grown monocrystalline silicon; and
wherein the method further includes:
forming a plurality of channel layers arranged on the first region to be spaced apart in a first direction parallel to a first surface of the substrate laminate and comprising a plurality of nanosheets, a plurality of gate structures extending in a second direction crossing the first direction, and a source/drain pattern located on both sides of each of the channel layers and located in a recess region of the substrate laminate; and
forming a plurality of channel layers arranged in the second region to be spaced apart in the first direction parallel to the first surface of the substrate laminate, a plurality of gate structures extending in the second direction crossing the first direction, and a source/drain region located on both sides of the each of the channel layers and formed by doping the substrate laminate.

20. The method of claim 18, wherein, during the removing of the second etch-stop layer, a step is formed on a lower surface of the substrate laminate.

21. (canceled)
